(19) United States
(12) Patent Application Publication
(10) Pub. No.: US 2020/0154584 A1
(43) Pub. Date: May 14, 2020

(54) Glass edging waste residue cleaning equipment

(71) Applicant: Jiali Chen, Fuzhou City (CN)

(72) Inventor: Jiali Chen, Fuzhou City (CN)

(21) Appl. No.: 16/746,860

(22) Filed: Jan. 18, 2020

(30) Foreign Application Priority Data
Oct. 12, 2019 (CN) 2019109693465

(51) Int. Cl. H05K 5/02; H05K 7/14

(52) U.S. Cl. CPC H05K 5/0247; H05K 7/1447

(57) ABSTRACT

A multifunctional hub according to the present invention includes a box body, and the box body is provided with a sliding cavity with an upward opening therein, and an annular slider is slidably slid in the sliding cavity. The multifunctional hub of the present invention has simple and clear operation, sensitive response, saving time and labor; at the same time, the device of the present invention is rich in functions, fixed and reliable, and highly practical.

### CROSS-REFERENCES TO RELATED APPLICATIONS

The present application claims priority from Chinese application No. 201910348287X filed on Apr. 28, 2019 which is hereby incorporated by reference in its entirety.

### FIELD OF TECHNOLOGY

The invention relates to the field of computer accessories, and in particular relates to a multifunctional hub.

### TECHNICAL FIELD

In places such as homes and offices, many different wires are often required to shuttle between the desktop or the bottom. The wires are of different lengths and will be cluttered if they are not organized. This affects the appearance and is not conducive to replacing or changing the wires. General hubs require both hands. The wire is manually wound on the hub, and the general hub cannot be fixed, it is easy to move around, rub against the ground, and contaminate the dust; in addition, when the general hub is on the desktop, the function is single and takes up extra space; therefore, it is necessary to design a Multifunctional hub to solve the above problems.

### CONTENT OF THE INVENTION

The technical problem to be solved by the present invention is to provide a multifunctional hub, which can solve the above-mentioned problems in the prior art.

The present invention is achieved by the following technical solution: A multifunctional hub of the present invention includes a box body, the box body is provided with a sliding cavity with an upward opening in the box body, and an annular slider is slidably provided in the sliding cavity. A fixed block is fixed on the outer end surface of the ring slider symmetrically on the left and right sides, a grip is fixed on the outer end surface of the fixed block, a locking tooth is fixed on the bottom surface of the fixed block, and a locking tooth is fixed on the top surface of the box body. A meshed annular end gear, an inner ring gear is provided on the inner side of the annular slider, a first cavity is provided in the bottom wall of the sliding cavity, and a spline is provided between the first cavity and the sliding cavity to rotate A spline shaft extending up and down in the spline sleeve; a gear meshing with the ring gear is fixed at the top of the spline shaft; the bottom surface of the ring slider and the top of the spline sleeve A first spring is connected between the surfaces, and a first disk is fixed at the bottom end of the spline shaft. A first groove with a downward opening is provided in the first disk, and the first groove is fixed in the first groove. With internal ratchet teeth, a second cavity is provided in the bottom wall of the first cavity, and the second cavity A first chute is communicated between the cavity and the first cavity, and a slide bar extending up and down is slidably arranged in the first chute, and a second disc is fixed on the top end of the slide bar. A rotating shaft is rotatably provided on the top wall of the two disks, and a pawl engaged with the internal ratchet teeth is fixed on the rotating shaft. A second spring is connected between the pawl and the top surface of the second disk. A third disk is fixed at the bottom end of the slide bar, a third spring is connected between the bottom surface of the third disk and the bottom wall of the second cavity, and a hydraulic cavity is provided in the bottom wall of the second cavity. A second chute is provided between the hydraulic chamber and the second cavity, a sealing ring is fixed on the outside of the second chute, and a first ejector rod is slidably arranged in the second chute, A magnet block fixedly connected to the first ejector rod is slidingly arranged in the hydraulic chamber, and a fourth spring is connected between the bottom surface of the magnet block and the bottom wall of the hydraulic chamber; therefore, the inner ring gear rotates to drive The gear rotates, the gear drives the first disc to rotate, and the magnet block drives the pawl to mesh with the inner ratchet teeth.

Preferably, the bottom wall of the sliding chamber is symmetrically provided with a third chute with an upward opening, and a second ejector rod is slidably arranged in the third chute, between the third chute and the hydraulic chamber. Hydraulic pipes are connected in communication, a winding groove is fixed on the outer surface of the first disc, a rear side end wall of the first cavity is provided with a wire inlet groove which opens backward, and the rear end of the first disc is A card slot is provided in the wall with a downward opening, and a second groove is connected to the front side of the card slot, and a card plate protruding into the card slot is provided in the second groove. A fifth spring is connected between the card plate and the upper and lower end walls of the second groove; therefore, the card wire groove and the card plate cooperate to fasten the wire material, and the winding groove rotates and winds the wire material.

Preferably, a ring magnet is fixed on the bottom surface of the box body, a magnet base can be adsorbed on the bottom end of the ring magnet, the magnet base repels the magnet block, and a rubber strip is fixed on the bottom end of the magnet base; Therefore, the ring magnet and the magnet base are attracted to fix the box body, and at the same time, the magnet base drives the magnet block to slide upward.

In summary, the beneficial effects of the present invention are: the multifunctional hub of the present invention has simple and clear operation, sensitive response, and saves time and labor; meanwhile, the device of the present invention is rich in functions, fixed and reliable, and highly practical.

### BRIEF DESCRIPTION OF THE DRAWINGS

For ease of description, the present invention is described in detail by the following specific embodiments and the accompanying drawings.

FIG. 1 is a schematic diagram of the overall structure of a multifunctional hub according to the present invention;

FIG. 2 is a schematic structural diagram of A-A in FIG. 1;

FIG. 3 is a schematic enlarged view of B in FIG. 1.

### DETAILED DESCRIPTION OF THE INVENTION

All features disclosed in this specification, or all disclosed methods or steps, other than mutually exclusive features and/or steps, may be combined in any manner.

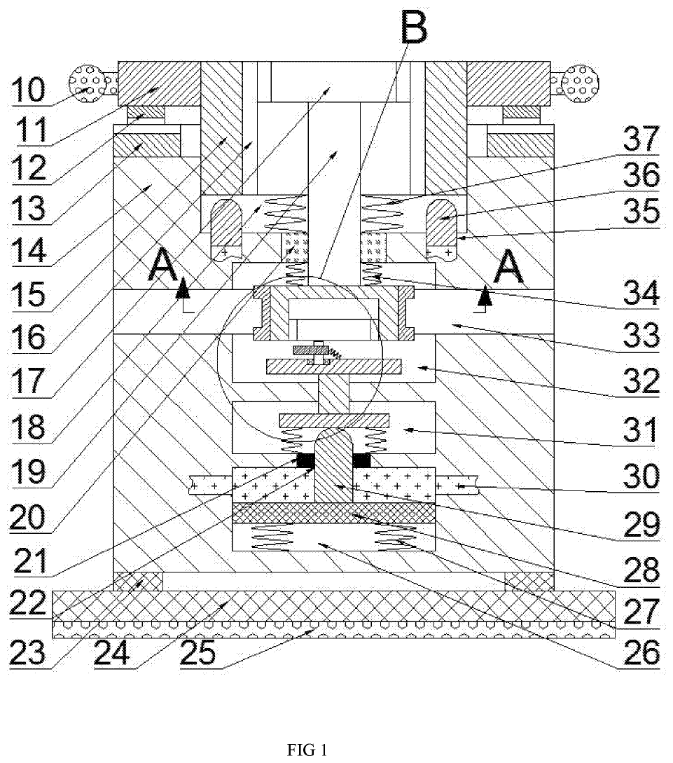

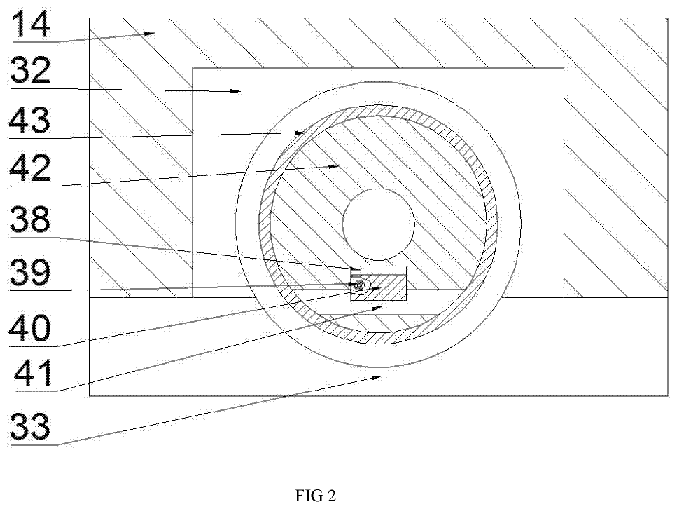

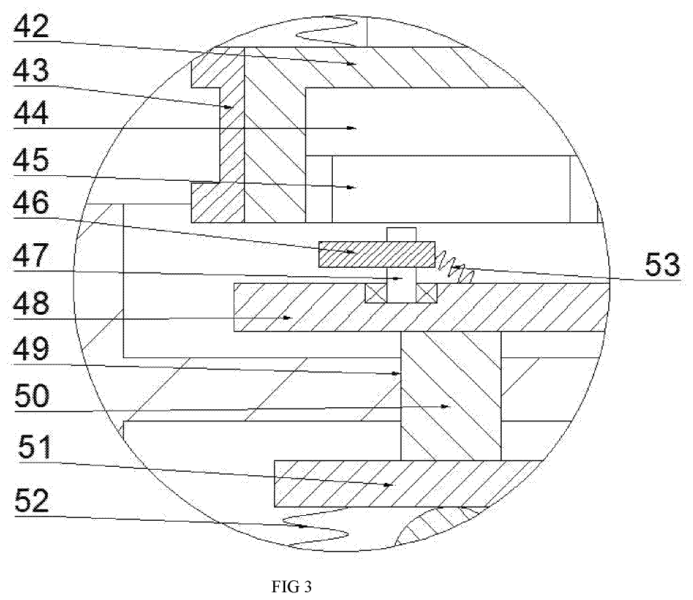

The present invention will be described in detail below with reference to FIGS. 1-3. Among them, for convenience of description, the orientation described below is specified as follows: the up-down, left-right, front-back direction described below is consistent with the up-down, left-right, front-back direction of the projection relationship of FIG.

As shown in FIGS. 1-3, a multifunctional hub of the present invention includes a box body 14, which is provided with a sliding cavity 18 with an upward opening therein, and an annular slider 15 is slidably provided in the sliding cavity 18. The left and right sides of the ring slider 15 are provided with fixing blocks 11 symmetrically fixed on the left and right sides, and the handle 10 is fixed on the outer end surface of the fixing block 11 with locking teeth 12 fixed on the bottom surface of the fixing block 11 and the box body 14. The top surface is fixedly provided with a ring-shaped end face gear 13 meshing with the locking teeth 12, an inner ring gear 16 is provided on the inner side of the ring slider 15, and a first cavity 32 is provided in the bottom wall of the sliding cavity 18. A spline sleeve 20 is rotatably provided between the first cavity 32 and the sliding cavity 18, and a spline shaft 19 extending up and down is slid in the spline sleeve 20, and the top end of the spline shaft 19 is fixedly provided with the spline shaft 19. A first spring 37 is connected between the bottom surface of the ring slider 15 and the top surface of the spline sleeve 20, and a first circle is fixed at the bottom end of the spline shaft 19. Disc 42, the first disc 42 is provided with a first groove 44 facing downwards, the first groove 44 is fixed with an internal ratchet 45, and the first cavity 32 is at the bottom A second cavity 31 is provided therein, and a first slide groove 49 is provided between the second cavity 31 and the first cavity 32 in communication. The first slide groove 49 is provided with a slide extending up and down. A rod 50 is provided with a second disk 48 fixed on the top end of the sliding rod 50. A rotating shaft 47 is rotatably provided on the top wall of the second disk 48, and the rotating shaft 47 is fixedly provided with a mesh with the internal ratchet teeth 45. A pawl 46, a second spring 53 is connected between the pawl 46 and the top surface of the second disc 48, and a third disc 51 is fixed at the bottom end of the slide bar 50; A third spring 52 is connected between the bottom surface of 51 and the bottom wall of the second cavity 31. A hydraulic cavity 26 is provided in the bottom wall of the second cavity 31, and the hydraulic cavity 26 and the second cavity 31 A second chute 22 is connected between the two, and a sealing ring 21 is fixed on the outside of the second chute 22. A first ejector rod 29 is slid in the second chute 22, and the hydraulic chamber 26 is slid. A magnet block 28 fixedly connected to the first ejector rod 29 is provided, and a fourth spring 27 is connected between the bottom surface of the magnet block 28 and the bottom wall of the hydraulic chamber 26; therefore, the ring gear 16 is driven to rotate The gear 17 rotates, Said gear 17 to drive the first rotating disk 42, while the magnet block 28 to drive the pawl 46 engages with the internal ratchet teeth 45.

Beneficially, a third sliding groove 35 with an upward opening is provided symmetrically in the bottom wall of the sliding cavity 18, and a second ejector rod 36 is slidably arranged in the third sliding groove 35. A hydraulic pipe 30 is communicated between the hydraulic chambers 26. A winding groove 43 is fixed on the outer surface of the first disc 42. A rear side end wall of the first cavity 32 is provided with a wire inlet groove opened rearwardly. 33. The rear end wall of the first disc 42 is provided with a card groove 41 with an opening downward. The front side of the card groove 41 is provided with a second groove 38 in the second groove 38. A card plate 40 is provided which extends into the card wire groove 41, and a fifth spring 39 is connected between the card plate 40 and the upper and lower end walls of the second groove 38; therefore, the card wire groove 41 and The clamping plate 40 is adapted to fasten the wire, and the winding groove 43 is rotatably wound around the wire.

Beneficially, a ring magnet 23 is fixed on the bottom surface of the box body 14. A magnet base 24 can be attracted to the bottom end of the ring magnet 23. The magnet base 24 repels the magnet block 28. A rubber strip 25 is fixed at the end; therefore, the ring magnet 23 and the magnet base 24 are fixed to fix the box body 14, and at the same time, the magnet base 24 drives the magnet block 28 to slide upward.

In the following, the applicant will refer to the accompanying drawings and the specific composition of a multifunctional hub of the present application described above to introduce its use in detail:

When the ring magnet 23 is not attracted to the magnet base 24, the ring end gear 13 meshes with the locking teeth 12 and the fixing block 11 cannot rotate. Before the hub is firmly fixed, the winder does not perform the winding function, so as to avoid the Everywhere

When the ring magnet 23 is attracted to the magnet base 24, the ring magnet 23 repels the magnet block 28, the magnet block 28 slides upward, the magnet block 28 drives the first ejector rod 29 to push the third disc 51, and the slider 50 slides on the ratchet The claw 46 is engaged with the internal ratchet teeth 45, and at this time, the winding can be normally wound into the winding groove without loosening;

At the same time, the magnet block 28 drives the second ejector pin 36 to slide upward through the hydraulic pipe 30. The second ejector pin 36 pushes the ring slider 15 upward, and the ring slider 15 slides upward to disengage the locking tooth 12 from the ring end face gear 13. The ring slider 15 can rotate, and at the same time, the height difference between the top surface of the gear 17 and the ring gear 16 forms a tea cup placement opening with an upward opening, which can stably place the tea cup;

Extend the wire into the wire slot 33, align the wire with the card slot 41, and fasten it into the card slot 41 from bottom to top. Then rotate the handle 10, the handle 10 drives the gear 17 to rotate, and the gear 17 drives the first A disk 42 rotates, and the first disk 42 drives the winding groove 43 to wind the wire to collect the wire. It does not need to be manually fixed during winding, and the operation is simple;

When you need to loosen the wire, press the gear 17, the gear 17 drives the spline shaft 19 to slide down, the spline shaft 19 drives the first disk 42 to slide down, and the first disk 42 slides down to make the internal ratchet teeth 45 and the pawl 46 is disconnected. At this time, the first disc 42 can be rotated in the reverse direction, that is, the wire is pulled to make the winding groove 43 reverse to loose the wire. When the cable is loosened and pressed, the hub plays the role of wire gathering again.

To sum up, the multifunctional hub of the present invention is simple and clear in operation, sensitive in response, time-saving and labor-saving; meanwhile, the device of the present invention is rich in functions, firmly fixed and practical.

The above are only specific embodiments of the invention, but the scope of protection of the invention is not limited to this. Any changes or substitutions that are not thought through without creative work should be covered by the scope of protection of the invention.

1. A multifunctional hub according to the present invention includes a box body, which is characterized in that the box body is provided with a sliding cavity with an upward opening therein, and an annular slider is slidably slid in the sliding cavity. A fixed block is fixedly provided, a grip is fixed on the outer end surface of the fixed block, locking teeth are fixed on the bottom surface of the fixed block, and a ring-shaped end face gear meshing with the locking teeth is fixed on the top surface of the box body. An inner ring gear is provided on the inner side of the annular slider, a first cavity is provided in the bottom wall of the sliding cavity, and a spline sleeve is arranged between the first cavity and the sliding cavity to rotate, and the spline sleeve A spline shaft extending up and down is provided inside, a gear meshing with the ring gear is fixed at the top of the spline shaft, and a first surface is connected between the bottom surface of the annular slider and the top surface of the spline sleeve. A spring, a first disc is fixedly provided at the bottom end of the spline shaft, and a first groove and a first groove with a downward opening are provided in the first disc; Ratchet teeth, a second cavity is provided in the bottom wall of the first cavity, and the second cavity and the first cavity A first chute is communicated between the cavities, and a slide bar extending up and down is slidably arranged in the first chute. A second disk is fixed at the top of the slide bar, and the top wall of the second disk is rotatably provided. There is a rotating shaft. A pawl that is engaged with the internal ratchet teeth is fixed on the rotating shaft. A second spring is connected between the pawl and the top surface of the second disc. The bottom end of the sliding rod is fixedly arranged. There is a third disc, a third spring is connected between the bottom surface of the third disc and the bottom wall of the second cavity, and a hydraulic cavity is arranged in the bottom wall of the second cavity, and the hydraulic cavity and the A second chute is communicated between the second cavities, a sealing ring is fixed outside the second chute, a first ejector rod is slidably disposed in the second chute, and a sliding device is disposed in the hydraulic cavity. There is a magnet block fixedly connected to the first jack, and a fourth spring is connected between the bottom surface of the magnet block and the bottom wall of the hydraulic chamber; therefore, the rotation of the ring gear drives the gear to rotate. The gear drives the first disc to rotate, while the magnet block drives the pawl to mesh with the inner ratchet teeth.

2. The multifunctional hub according to claim 1, characterized in that: a third sliding groove with an upward opening is symmetrically provided in the bottom wall of the sliding cavity, and a second ejector rod is slidably provided in the third sliding groove. A hydraulic pipeline is provided between the third chute and the hydraulic chamber. A winding groove is fixed on the outer surface of the first disc. An end wall of the rear side of the first cavity is provided with an opening backward. A cable entry slot is provided in the rear end wall of the first disc, and a card slot is opened downward in the front end wall. A second groove is connected to the front side of the card slot, and a second slot is provided in the second slot. A card spring protruding into the card wire groove, and a fifth spring is connected between the card plate and the upper and lower end walls of the second groove; therefore, the card wire groove and the card plate cooperate to fasten the wire. The winding groove rotates and winds the wire.

3. The multifunctional hub according to claim 1, characterized in that: a ring magnet is fixed on the bottom surface of the box body, a magnet base can be adsorbed on the bottom end of the ring magnet, and the magnet base is in phase with the magnet block A rubber strip is fixed at the bottom end of the magnet base; therefore, the ring magnet and the magnet base are fixed to fix the box body, and at the same time, the magnet base drives the magnet block to slide upward.
